(19) United States
(12) Patent Application Publication
(10) Pub. No.: US 2023/0042957 A1
(43) Pub. Date: Feb. 9, 2023

(54) LIDAR DEVICE

(71) Applicant: HL KLEMOVE CORP., Incheon (KR)

(72) Inventors: Yun Ki Han, Gyeonggi-do (KR); HoSeok Shin, Gyeonggi-do (KR); HakGu Han, Gyeonggi-do (KR); Chuiseung Lee, Gyeonggi-do (KR); Yong Min Park, Gyeonggi-do (KR); Hyuk Ryu, Seoul (KR)

(21) Appl. No.: 17/882,477

(22) Filed: Aug. 5, 2022

(30) Foreign Application Priority Data
Aug. 6, 2021 (KR) 10-2021-0103742

(51) Int. Cl. G01S 7/4861; G01S 17/02; G01S 7/481; G01S 7/4865

(52) U.S. Cl. CPC G01S 7/4861; G01S 17/02; G01S 7/4816; G01S 7/4814; G01S 7/4817; G01S 7/4865; G01S 17/931

(57) ABSTRACT

A light detection and ranging (LIDAR) device according to one embodiment of the present disclosure includes: a light transmitting unit including a plurality of laser transmission channels for transmitting laser light for detecting an external object in an allocated transmission time slot; a light receiving unit including a plurality of laser reception channels for receiving the laser light reflected by the external object in a reception time slot allocated to correspond to the transmission time slot, N laser reception channels (N is a natural number greater than or equal to 2) being allocated to each of the reception time slots; and a signal amplification unit configured to sequentially amplify the laser light received by the light receiving unit according to the order of the reception time slots, and having N channels allocated in one-to-one correspondence with the N laser reception channels for each of the reception time slots.

### CROSS-REFERENCE TO RELATED APPLICATION

This application claims priority to and the benefit of Korean Patent Application No. 2021-0103742, filed on Aug. 6, 2021, the disclosure of which is incorporated herein by reference in its entirety.

### BACKGROUND

### 1. Field of the Invention

The present disclosure relates to a light detection and ranging (LIDAR) device, and more particularly, to a LIDAR device for detecting an external object through laser light.

### 2. Discussion of Related Art

Light detection and ranging (LIDAR) is a radar system that uses laser pulses to measure a distance to an external object. The LIDAR device irradiates a surrounding area with laser light and measures the time during which the irradiated light is reflected by an object to be measured and is returned to measure a distance to the object to be measured, a shape of the object to be measured, and the like.

Recently, LIDAR devices have been widely used in autonomous vehicles, mobile robots, and the like. For stable operation of the autonomous vehicles and the mobile robots, the surrounding terrain must be accurately identified. To this end, LIDAR devices need to have a high resolution.

In general, the resolution of the LIDAR depends on the number of channels of a detector receiving light. When an array detector having many channels is disposed in a light receiving unit, a high resolution can be obtained. However, as the number of detector channels increases, the number of elements required to amplify and detect an optical signal at the rear end of the detector also increases. Accordingly, there is a problem that a LIDAR system is enlarged, and the manufacturing cost is also increased.

In this situation, there is a demand for the development of a technology which can reduce the number of elements at the rear end of the detector while securing a high level of vertical resolution of the LIDAR, thereby suppressing the increase in the size of the LIDAR system and reducing the manufacturing cost.

### PRIOR ART DOCUMENT

### Patent Document

Korean Patent Publication No. 10-2020-0076989 “Around view monitoring apparatus and method using LIDAR”, published on Jun. 30, 2020

### SUMMARY OF THE INVENTION

The present disclosure is directed to providing a LIDAR device which can reduce the number of elements at a rear end of a detector while securing a high level of vertical resolution, thereby suppressing an increase in size of a LIDAR system and reducing the manufacturing cost.

According to an aspect of the present disclosure, there is provided a LIDAR device including: a light transmitting unit including a plurality of laser transmission channels for transmitting laser light for detecting an external object in an allocated transmission time slot; a light receiving unit including a plurality of laser reception channels for receiving the laser light reflected by the external object in a reception time slot allocated to correspond to the transmission time slot, wherein N laser reception channels (N is a natural number equal to or greater than 2) are allocated to each of the reception time slots; and a signal amplification unit configured to sequentially amplify the laser light received by the light receiving unit according to an order of the reception time slots, and having N channels allocated in one-to-one correspondence with the N laser reception channels for each of the reception time slots.

In this case, the LIDAR device may further include a transmitting optical system arranged on a transmission path of the laser light transmitted from the light transmitting unit, and configured to form an angle between the laser light and a horizontal axis on the transmission path differently for each laser transmission channel.

In addition, the transmitting optical system may form an angle between the plurality of laser transmission channels provided in the light transmitting unit and the horizontal axis in a range of −6° to 6°.

In addition, the LIDAR device may further include a receiving optical system arranged on a reception path through which the light receiving unit receives the laser light, and configured to form directional angles of the plurality of laser reception channels provided in the light receiving unit differently for each of the laser reception channels.

In addition, the transmission time slot and the reception time slot may be set to 2 to 3 μs.

In addition, the transmission time slot and the reception time slot may be allocated so that T time slots (T is a natural number greater than or equal to 2) scan a vertical scan range once, the light transmitting unit may include T laser transmission channels to which any one of the T transmission time slots is allocated without overlapping, and the light receiving unit may include T×N laser reception channels, and the N laser reception channels may be allocated to each of the reception time slots without overlapping.

In this case, T may be the same as N.

In addition, each of the laser transmission channels may include an edge emitting laser diode.

In addition, the transmission time slots and the reception time slots may be allocated so that T time slots (T is a natural number greater than or equal to 2) scan a vertical scan range once, the light transmitting unit may include T×N laser transmission channels, N laser transmission channels may be allocated to each of the transmission time slots without overlapping, the light receiving unit may include N laser reception channels, and the N laser reception channels may be allocated to each of the reception time slots.

In this case, T may be the same as N.

In addition, each of the laser transmission channels may include a vertical cavity surface emitting laser (VCSEL) diode.

In addition, the LIDAR device may further include a signal detection unit configured to detect a signal related to distance calculation from a signal output value of the signal amplification unit.

In addition, the signal detection unit may detect the signal related to the distance calculation in an analog to digital converter (ADC) method.

In addition, the signal detection unit may detect the signal related to the distance calculation in a time to digital converter (TDC) method.

In addition, the LIDAR device may further include a scanner including a transmission mirror for reflecting the laser light transmitted from the light transmitting unit to the outside, and a reception mirror for reflecting the laser light reflected from the outside to the light receiving unit.

In addition, the scanner may rotate about a vertical axis.

In addition, the transmission mirror may form a horizontal divergence angle of the laser light transmitted from the light transmitting unit to be 0.10° to 0.12°, and the reception mirror may form a horizontal viewing angle of the laser light reflected to the light receiving unit to be 0.11° to 0.13°.

According to one embodiment of the present disclosure, it is possible to reduce the number of elements at the rear end of a detector while ensuring high resolution through a light transmitting unit that time-divisionally transmits laser light, a light receiving unit that sequentially receives the time-divisionally transmitted laser light, and a signal amplification unit, thereby minimizing an increase in size of a system and reducing the manufacturing cost.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a configuration diagram of a light detection and ranging (LIDAR) device according to one embodiment of the present disclosure;

FIG. 2 is a diagram illustrating an example of a light transmitting unit and a transmitting optical system of the LIDAR device according to one embodiment of the 5 present disclosure;

FIG. 3 is a diagram illustrating another example of the light transmitting unit and the transmitting optical system of the LIDAR device according to one embodiment of the present disclosure;

FIG. 4 is a diagram illustrating an example of a light receiving unit and a receiving optical system of the LIDAR device according to one embodiment of the present disclosure;

FIG. 5 is a diagram illustrating another example of the light receiving unit and the receiving optical system of the LIDAR device according to one embodiment of the present disclosure;

FIG. 6 is a diagram illustrating an example of a scanner of the LIDAR device according to one embodiment of the present disclosure;

FIG. 7 is a diagram illustrating an example of the configuration and operation of the LIDAR device according to one embodiment of the present disclosure; and

FIG. 8 is a diagram illustrating another example of the configuration and operation of the LIDAR device according to one embodiment of the present disclosure.

### DETAILED DESCRIPTION OF EXEMPLARY EMBODIMENTS

Hereinafter, embodiments of the present disclosure will be described in detail so that those of ordinary skill in the art to which the present disclosure pertains can easily implement them. However, the present disclosure may be embodied in various different forms and is not limited to the embodiments described herein. In addition, parts irrelevant to the description will be omitted to clearly describe the embodiments of the present disclosure, and like reference numerals are given to like components throughout the specification.

In the specification, it should be understood that the terms such as “comprise” or “have” are intended to indicate the presence of features, numbers, steps, acts, components, parts or combinations thereof disclosed in the specification and are not intended to exclude the possibility of the presence or addition of one or a plurality of other features, numbers, steps, acts, components, parts or combinations thereof.

In this specification, spatially relative terms “front”, “rear”, “upper” or “lower” may be used to describe a correlation with the components shown in the drawings. These are relative terms determined based on what is shown in the drawings, and the positional relationship may be conversely interpreted according to the orientation.

The presence of an element “in front”, “behind”, “above” or “below” of another element means that, unless otherwise specified, it is directly in contact with another element, such as “front”, “rear”, “above” or “below”. It includes not only being disposed in the “lower part” but also cases in which another component is disposed in the middle. In addition, that a component is “connected” with another component includes not only direct connection to each other, but also indirect connection to each other, unless otherwise specified.

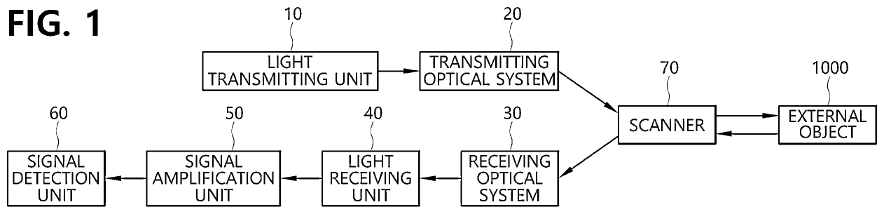

FIG. 1 is a block diagram illustrating a light detection and ranging (LIDAR) device according to one embodiment of the present disclosure.

The LIDAR device according to one embodiment of the present disclosure transmits laser light to a surrounding area and measures the time it takes for the transmitted laser light to be reflected by an external object 1000 and return, thereby measuring a distance to the external object 1000. The LIDAR device according to one embodiment of the present disclosure may time-divisionally transmit laser light and may sequentially process the laser light reflected by the external object 1000 and returned according to the transmission order, thereby reducing the number of elements that process a received laser light signal.

Referring to FIG. 1, the LIDAR device according to one embodiment of the present disclosure may include a light transmitting unit 10, a transmitting optical system 20, a receiving optical system 30, a light receiving unit 40, a signal amplification unit 50, a signal detection unit 60, and a scanner 70.

The light transmitting unit 10 transmits laser light to the outside. The light transmitting unit 10 includes a plurality of laser transmission channels for transmitting laser light for detecting the external object 1000 in an allocated transmission time slot. For example, the transmission time slot may be set to 2 to 3 μs.

The plurality of laser transmission channels may be individually switched (on/off) with a time difference. For example, the laser transmission channel of the light transmitting unit 10 may include any one or more of a VCSEL and an edge emitting laser diode device.

The plurality of laser transmission channels may be vertically stacked and arranged. In one embodiment of the present disclosure, the plurality of laser transmission channels may be vertically stacked and arranged, and each of the laser transmission channels may transmit a laser in a horizontal direction.

The transmitting optical system 20 may be arranged on a transmission path of the laser light transmitted from the light transmitting unit 10, and may form an angle between the laser light and a horizontal axis differently for each of the laser transmission channels on the transmission path. That is, the transmitting optical system 20 may steer an angle formed by a traveling direction of the transmitted laser light with the horizontal axis differently for each of the laser transmission channels.

In one embodiment of the present disclosure, the transmitting optical system 20 may form an angle formed between the plurality of laser transmission channels provided in the light transmitting unit 10 and the horizontal axis in a range of −10° to 10°.

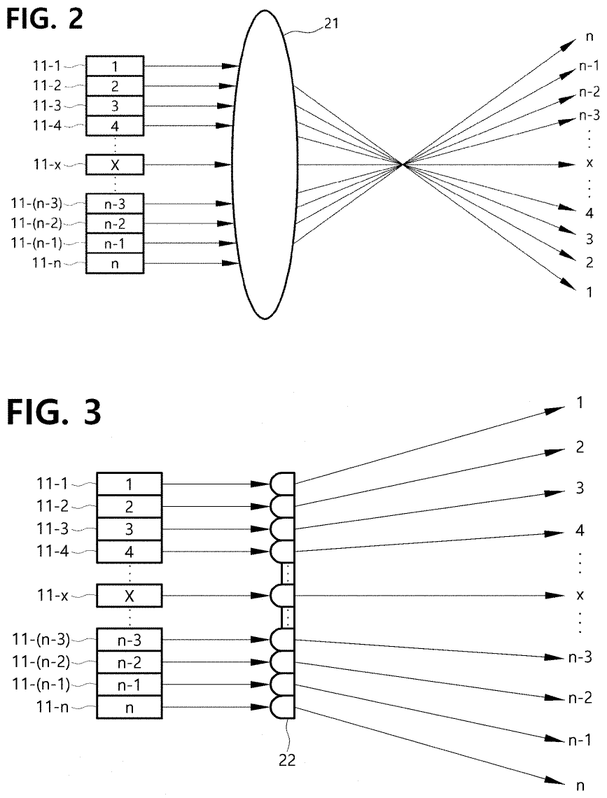

FIG. 2 is a diagram illustrating an example of the light transmitting unit and the transmitting optical system of the LIDAR device according to one embodiment of the present disclosure.

Referring to FIG. 2, the light transmitting unit 10 may include n laser transmission channels 11-1, 11-2, . . . , and 11-n. In addition, the transmitting optical system 20 may include a lens 21. For example, the lens 21 may be a cylindrical lens, an acylindrical lens, a spherical lens, or an aspherical lens.

The n laser transmission channels 11-1, 11-2, . . . , and 11-n may be vertically stacked and arranged. Each of the n laser transmission channels 11-1, 11-2, . . . , and 11-n transmits laser light in a transmission time slot allocated thereto.

In this case, the laser light which is transmitted from an x-th laser transmission channel 11-x and is incident on a center of the lens 21 may proceed in parallel in the horizontal direction, and the laser light which is transmitted from the laser transmission channels arranged in an upper portion of the x-th laser transmission channel 11-x and is incident on an upper portion of the lens 21 may pass through the lens 21, may be refracted downward, and may proceed. In addition, the laser light which is transmitted from the laser transmission channels arranged in a lower portion of the x-th laser transmission channel 11-x and is incident on a lower portion of the lens 21 may pass through the lens 21, may be refracted upward, and may proceed.

FIG. 3 is a diagram illustrating another example of the light transmitting unit and the transmitting optical system of the LIDAR device according to one embodiment of the present disclosure.

Referring to FIG. 3, the light transmitting unit 10 may include n laser transmission channels 11-1, 11-2, . . . , and 11-n. In addition, the transmitting optical system 20 may include a microlens array 22.

The n laser transmission channels 11-1, 11-2, . . . , and 11-n may be vertically stacked and arranged. Each of the n laser transmission channels 11-1, 11-2, . . . , and 11-n transmits laser light in a transmission time slot allocated thereto.

In this case, the laser light which is transmitted from an x-th laser transmission channel 11-x and is incident on a center of the microlens array 22 may proceed in parallel in the horizontal direction, and the laser light which is transmitted from the laser transmission channels arranged in an upper portion of the x-th laser transmission channel 11-x and is incident on an upper portion of the microlens array 22 may pass through the lens 21, may be refracted upward, and may proceed. In addition, the laser light which is transmitted from the laser transmission channels arranged in a lower portion of the x-th laser transmission channel 11-x and is incident on a lower portion of the microlens array 22 may pass through the lens 21, may be refracted downward, and may proceed.

In the examples shown in FIGS. 2 and 3, an interval of an angle between the laser light transmitted from the n laser transmission channels 11-1, 11-2, . . . , and 11-n and the horizontal axis may be formed uniformly or may be formed irregularly. In addition, a vertical divergence angle of each laser transmission channel may be set to be less than or equal to the vertical resolution required by the LIDAR device.

The receiving optical system 30 may be arranged on a reception path for receiving the laser light reflected from the external object 1000 and returned, and may form a directional angle of a plurality of laser reception channels provided in the light receiving unit differently for each of the laser reception channels.

The light receiving unit 40 may include the plurality of laser reception channels for receiving the laser light reflected by the external object 1000 in a reception time slot assigned to correspond to the transmission time slot. In the light receiving unit 40, N (N is a natural number equal to or greater than 2) laser reception channels may be allocated per one reception time slot. For example, the reception time slot may be set to 2 to 3 μs.

The plurality of laser reception channels may be vertically stacked and arranged. In one embodiment of the present disclosure, the plurality of laser reception channels may be vertically stacked and arranged and may have different directional angles for each channel through the receiving optical system 30.

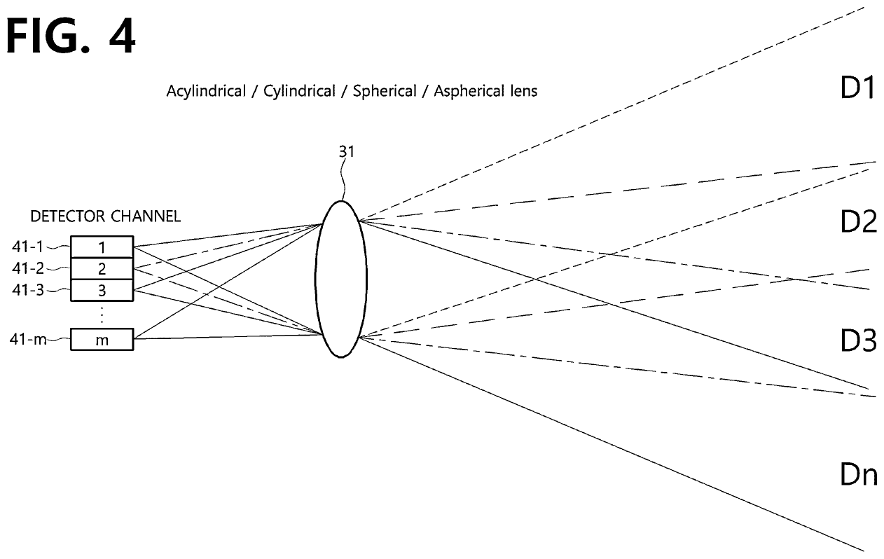

FIG. 4 is a diagram illustrating an example of the light receiving unit and the receiving optical system of the LIDAR device according to one embodiment of the present disclosure.

Referring to FIG. 4, the light receiving unit 40 may include m laser reception channels 41-1, 41-2, . . . , and 41-m. In addition, the receiving optical system 30 may include a lens 31. For example, the lens 31 may be a cylindrical lens, an acylindrical lens, a spherical lens, or an aspherical lens.

In each of the m laser reception channels 41-1, 41-2, . . . , and 41-m, a vertical directional angle (range) is determined through the lens 31 arranged on a reception path of the laser light. In FIG. 4, a first laser reception channel 41-1 is oriented to a region Dm, a second laser reception channel 41-2 is oriented to a region D3, a third laser reception channel 41-3 is oriented to a region D2, and an m-th laser reception channel 41-m is oriented to a region D1. Here, the regions D1 to Dm may divide and cover the entire vertical detection angle of the LIDAR device without overlapping. FIG. 5 is a diagram illustrating another example of the light receiving unit and the receiving optical system of the LIDAR device according to one embodiment of the present disclosure.

Referring to FIG. 5, the light receiving unit 40 may include n laser reception channels 41-1, 41-2, . . . , and 41-n. In addition, the receiving optical system 30 may include a lens 31 and a microlens array 32. For example, the lens 31 may be a cylindrical lens, an acylindrical lens, a spherical lens, or an aspherical lens.

With respect to viewing directions displayed on the right side of the lens 31 in FIG. 5, laser light which is reflected in an X-th viewing direction and is incident parallel to a center of the lens 31 may pass through the microlens array 32 and may then proceed to an x-th laser reception channel 11-x, and laser light which is incident from a lower side to the center side with respect to the center of the lens 31, such as an n-th viewing direction, or the like may pass through the microlens array 32 according to an incident angle thereof, and then may proceed to a first laser reception channel 11-1, or the like arranged on the x-th laser reception channel 11-x. In addition, laser light which is incident from an upper side to the center side with respect to the center of the lens 31 such as a first viewing direction, or the like may pass through the microlens array 32 according to an incident angle thereof, and then may proceed to an n-th laser reception channel 11-n, or the like arranged below the x-th laser reception channel 11-x.

Assuming that n is greater than m (e.g., n is 16 and m is 4) in FIGS. 4 and 5, when the receiving optical system 30 and the light receiving unit 40 are configured as shown in FIG. 4, a single laser reception channel may cover a relatively wide vertical area, and a plurality of laser transmission channels may be arranged to correspond to the vertical area covered by the single laser reception channel.

On the other hand, when the receiving optical system 30 and the light receiving unit 40 are configured as shown in FIG. 5, a single laser reception channel may cover a relatively narrow vertical area, and the laser reception channel and the laser transmission channel may correspond one-to-one. Alternatively, on the premise that the laser transmission channel irradiates laser light covering a relatively wide vertical area, a plurality of laser reception channels may correspond to one laser transmission channel.

The signal amplification unit 50 sequentially amplifies the laser light received by the light receiving unit 40 according to the order of the reception time slots. The signal amplification unit 50 may include N channels that are assigned one-to-one correspondence with N laser reception channels per one reception time slot.

The signal amplification unit 50 may include a device which can sequentially process a time-division multiplexed signal. For example, the signal amplification unit 50 may include a transimpedance amplifier (TIA).

The signal detection unit 60 detects a signal related to distance calculation from a signal output value of the signal amplification unit 50. The signal detected by the signal detection unit 60 is used for distance extraction. For example, distance extraction may be performed by a device such as a field programmable gate array (FPGA), microcontroller (MCU), or time to digital converter (TDC).

The signal detection unit 60 may detect the signal related to the distance calculation in an analog to digital converter (ADC) method. In this case, as the distance extraction method, a method of measuring a distance by detecting a waveform similar to a waveform oscillated by the light transmitting unit 10 in a waveform method may be applied.

The ADC method has the advantage of enabling lower signal detection compared to a time to digital converter (TDC) method, which will be discussed below, even if there is ambient light noise such as sunlight noise. In addition, in the case of the ADC method, it is possible to check intensity information because the analog signal is viewed. Accordingly, it is possible to detect targets having different reflectances located at the same distance. For example, a road and a crosswalk on the road can be detected at the same time.

The signal detection unit 60 may detect the signal related to the distance calculation in the TDC method. In this case, as the distance extraction method, a method of amplifying an incident signal and measuring a time exceeding a reference threshold voltage may be used. The TDC method has the advantage of being able to detect a signal at a higher signal-to-noise ratio (SNR) compared to the ADC method.

The scanner 70 emits the laser light transmitted from the light transmitting unit 10 in the horizontal direction, and advances the laser light, which is reflected by the external object 1000 after being emitted in the horizontal direction and returned, toward the light receiving unit 40.

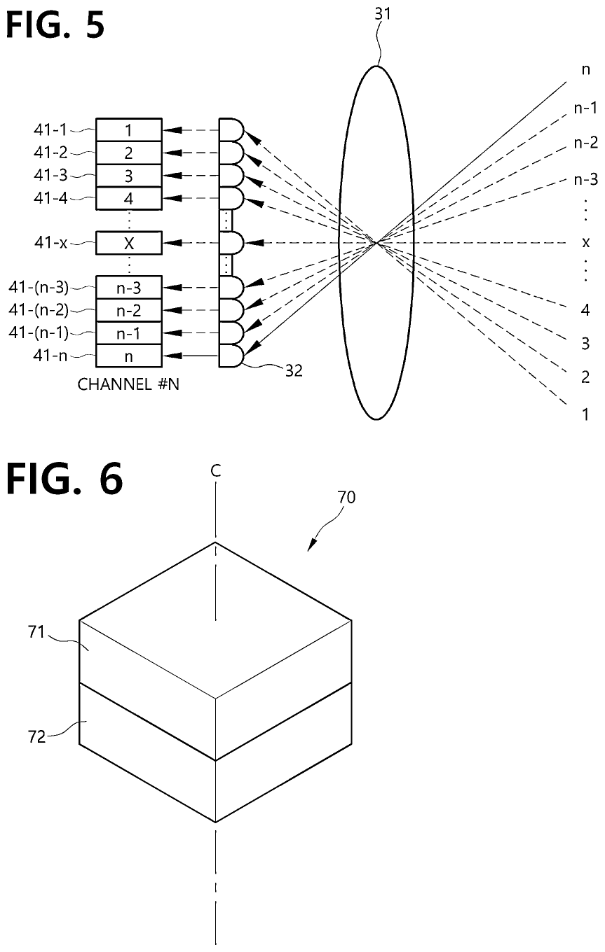

Referring to FIG. 6, in one embodiment of the present disclosure, the scanner 70 may include a transmission mirror 71 for reflecting the laser light transmitted from the light transmitting unit 10 to the external object 1000, and a reception mirror 72 for reflecting the laser light reflected from the external object 1000 to the light receiving unit 40.

The transmission mirror 71 and the reception mirror 72 may be vertically stacked. In addition, the transmission mirror 71 and the reception mirror 72 may each have four surfaces and may form a rectangular box shape as a whole. Of course, this is only one example, and the arrangement, the number of surfaces, and the shape of the transmission mirror 71 and the reception mirror 72 in the scanner 70 may be changed as necessary.

The scanner 70 may rotate about a vertical axis C. For this purpose, a component (e.g., a driving motor, etc.) for rotational driving may be provided.

According to one embodiment of the present disclosure, in the scanner 70, the transmission mirror 71 may form a horizontal divergence angle of the laser light transmitted from the light transmitting unit 10 to be 0.10° to 0.12°, and the reception mirror 72 may form a horizontal viewing angle of the laser light reflected to the light receiving unit 40 to be 0.11° to 0.13°.

Hereinafter, a practical configuration and operation concept of the LIDAR device according to one embodiment of the present disclosure will be described.

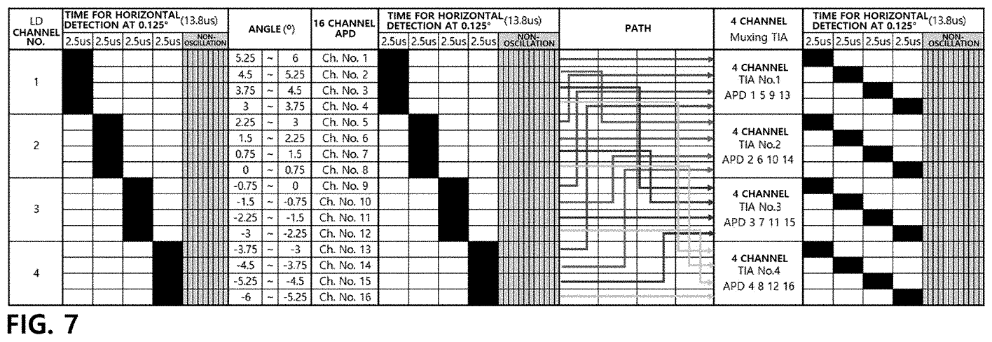

FIG. 7 is a diagram illustrating an example of the configuration and operation of the LIDAR device according to one embodiment of the present disclosure.

Referring to FIG. 7, the light transmitting unit 10 includes four laser transmission channels. The laser transmission channel may be an edge emitting laser diode of 4 channels. In addition, the light receiving unit 40 includes 16 laser reception channels. The 16 laser reception channels are oriented by dividing the range by 0.75° in the range of −6° to 6° with respect to the horizontal axis. Such directivity may be formed by the transmitting optical system 20 and the receiving optical system 30 as described above.

At this time, four transmission time slots and four reception time slots are allocated to each scan a vertical scan range once, and one transmission time slot and one reception time slot are each set to 2.5 μs. In addition, horizontal scan may be set in such a manner that 13.8 μs is required for horizontal detection at 0.125°. Of course, this is exemplary, and one transmission time slot, one reception time slot, horizontal scan time, etc., may be changed as needed. The length of the transmission time slot and the reception time slot is related to the detection distance, and when the length of the transmission time slot and the reception time slot is 2 μs, the detection distance may be 300 m.

A laser transmission channel #1 (LD Ch. No. 1) transmits laser light in a first transmission time slot, and laser reception channels #1 to #4 (Ch. No. 1 to Ch. No. 4 of 16 channel APDs) simultaneously receive the reflected and returned laser light in a first reception time slot. A laser transmission channel #2 (LD Ch. No. 2) transmits laser light in a second transmission time slot, and laser reception channels #5 to #8 (Ch. No. 5 to Ch. No. 8 of 16 channel APDs) simultaneously receive the reflected and returned laser light in a second reception time slot. A laser transmission channel #3 (LD Ch. No. 3) transmits laser light in a third transmission time slot, and laser reception channels #9 to #12 (Ch. No. 9 to Ch. No. 12 of 16 channel APDs) simultaneously receive the reflected and returned laser light in a third reception time slot. A laser transmission channel #4 (LD Ch. No. 4) transmits laser light in a fourth transmission time slot, and laser reception channels #13 to #16 (Ch. No. 13 to Ch. No. 16 of 16 channel APDs) simultaneously receive the reflected and returned laser light in a fourth reception time slot.

Meanwhile, the signal amplification unit 50 may be constituted of a 4-channel TIA (4-channel multiplexing TIA). The signal amplification unit 50 processes laser light received by four laser reception channels one by one in each reception time slot. More specifically, a TIA channel #1 (4-channel TIA No. 1) may sequentially amplify the laser light received by the channels #1, #5, #9, and #13 among the laser reception channels according to the order of the reception time slots, a TIA channel #2 (4-channel TIA No. 2) may sequentially amplify the laser light received by the channels #2, #6, #10, and #14 among the laser reception channels according to the order of the reception time slots, a TIA channel #3 (4-channel TIA No. 3) may sequentially amplify the laser light received by the channels #3, #7, #11, and #15 among the laser reception channels according to the order of the reception time slots, and a TIA channel #4 (4-channel TIA No. 4) may sequentially amplify the laser light received by the channels #4, #8, #12, and #16 among the laser reception channels according to the order of the reception time slots.

As shown in FIG. 7, in one embodiment of the present disclosure, the transmission time slot and the reception time slot are allocated so that T (T is a natural number greater than or equal to 2) time slots scan a vertical scan range once, the light transmitting unit 10 includes T laser transmission channels to which any one of the T transmission time slots is allocated without overlapping, the light receiving unit 40 includes T×N laser reception channels, and N laser reception channels may be allocated to each reception time slot without overlapping.

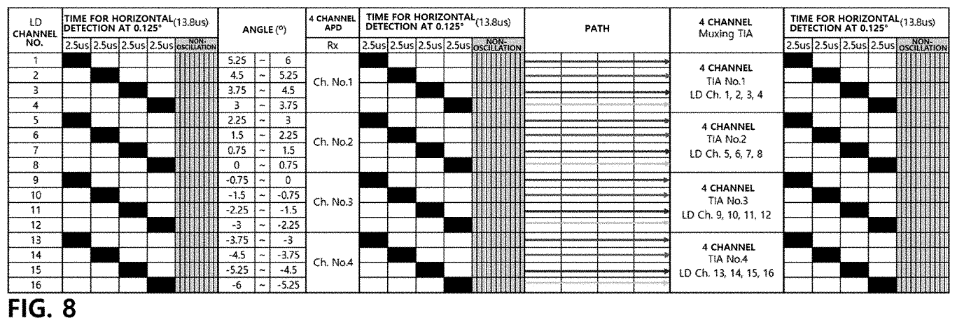

FIG. 8 is a diagram illustrating another example of the configuration and operation of the LIDAR device according to one embodiment of the present disclosure. Referring to FIG. 8, the light transmitting unit 10 includes 16 laser transmission channels. The laser transmission channel may be a vertical cavity surface emitting laser (VCSEL) diode. In addition, the light receiving unit 40 includes four laser reception channels. The four laser reception channels are oriented by dividing the range by 3° in the range of −6° to 6° with respect to the horizontal axis. Four laser transmission channels correspond to one laser reception channel, and a vertical divergence angle between adjacent laser transmission channels is formed with a difference of 0.75°. Such directivity may be formed by the transmitting optical system 20 and the receiving optical system 30 as described above.

Similar to the operation concept discussed above, four transmission time slots and four reception time slots are assigned to each scan the vertical scan range once, and one transmission time slot and one reception time slot are each set to 2.5 μs. In addition, a horizontal scan may be set in such a manner that 13.8 μs is required for horizontal detection at 0.125°. Of course, this is exemplary, and one transmission time slot, one reception time slot, horizontal scan time, etc., may be changed as needed. The length of the transmission time slot and the reception time slot is related to the detection distance, and when the length of the transmission time slot and the reception time slot is 2 μs, the detection distance may be 300 m.

Laser transmission channels #1, #5, #9, and #13 (LD Ch. Nos. 1, 5, 9, and 13) among the laser transmission channels transmit the laser light in a first transmission time slot, and laser reception channels #1 to #4 (Ch. No. 1 to Ch. No. 4 of 4 channel APDs) correspond one-to-one to simultaneously receive the reflected and returned laser light in a first reception time slot. Laser transmission channels #2, #6, #10, and #14 (LD Ch. Nos. 2, 6, 10, and 14) among the laser transmission channels transmit the laser light in a second transmission time slot, and the laser reception channels #1 to #4 (Ch. No. 1 to Ch. No. 4 of 4 channel APDs) correspond one-to-one to simultaneously receive the reflected and returned laser light in a second reception time slot. Laser transmission channels #3, #7, #11, and #15 (LD Ch. Nos. 3, 7, 11, and 15) among the laser transmission channels transmit the laser light in a third transmission time slot, and the laser reception channels #1 to #4 (Ch. No. 1 to Ch. No. 4 of 4 channel APDs) correspond one-to-one to simultaneously receive the reflected and returned laser light in a third reception time slot. Laser transmission channels #4, #8, #12, and #16 (LD Ch. Nos. 4, 8, 12, and 16) among the laser transmission channels transmit the laser light in a fourth transmission time slot, and the laser reception channels #1 to #4 (Ch. No. 1 to Ch. No. 4 of 4 channel APDs) correspond one-to-one to simultaneously receive the reflected and returned laser light in a fourth reception time slot.

Meanwhile, the signal amplification unit 50 may be constituted of a 4-channel TIA (4-channel multiplexing TIA). The signal amplification unit 50 processes laser light received by four laser reception channels one by one in each reception time slot. More specifically, a TIA channel #1 (4-channel TIA No. 1) sequentially amplifies the laser light received by the channels #1 to #4 among the laser reception channels according to the order of the reception time slots, a TIA channel #2 (4-channel TIA No. 2) sequentially amplifies the laser light received by the channels #5 to #8 among the laser reception channels according to the order of the reception time slots, a TIA channel #3 (4-channel TIA No. 3) sequentially amplifies the laser light received by the channels #9 to #12 among the laser reception channels according to the order of the reception time slots, and a TIA channel #4 (4-channel TIA No. 4) sequentially amplifies the laser light received by the channels #13 to #16 among the laser reception channels according to the order of the reception time slots.

As shown in FIG. 8, in one embodiment of the present disclosure, the transmission time slot and the reception time slot are allocated so that T (T is a natural number greater than or equal to 2) time slots scan a vertical scan range once, the light transmitting unit 10 includes T×N laser transmission channels, N laser transmission channels may be allocated for each transmission time slot without overlapping, the light receiving unit 40 may include N laser reception channels, and the N laser reception channels may be allocated for each reception time slot.

When the LIDAR device is configured as shown in FIG. 8, laser light is transmitted from a plurality of channels that are physically spaced apart from each other in one time slot. Accordingly, crosstalk can be reduced compared to a case in which laser light is transmitted simultaneously from adjacent channels.

According to one embodiment of the present disclosure, vertical resolution can be increased. For example, the vertical resolution can be increased without increasing the number of laser reception channels of the light receiving unit 40 while a VCSEL having a relatively high number of channels is applied to the laser transmission channel. In addition, even if an edge emitting laser diode having a low channel number is applied to the laser transmission channel, the vertical resolution can be increased by increasing the number of laser reception channels of the light receiving unit 40.

In addition, according to one embodiment of the present disclosure, since a vertical scanner is not separately used, durability and stability can be secured. In particular, since the plurality of laser transmission channels transmit laser light in a time-division manner and do not oscillate at the same time, heat generation, amount of current, and electromagnetic interference (EMI) noise can be minimized.

In addition, according to one embodiment of the present disclosure, it is advantageous to increase the maximum detection distance performance. For example, when the VCSEL is applied to the laser transmission channel, the power increases in proportion to the emission area, thereby increasing the detection distance.

Although one embodiment of the present disclosure has been described, the spirit of the present disclosure is not limited to the embodiment disclosed herein, and it should be understood that those skilled in the art can devise numerous other embodiments falling within the same spirit and scope of this disclosure through addition, modification, removal, supplementation, and the like of a component, and these other embodiments will also fall within the spirit and scope of the present disclosure.

What is claimed is:

1. A light detection and ranging (LIDAR) device comprising:
a light transmitting unit including a plurality of laser transmission channels for transmitting laser light for detecting an external object in an allocated transmission time slot;
a light receiving unit including a plurality of laser reception channels for receiving the laser light reflected by the external object in a reception time slot allocated to correspond to the transmission time slot, wherein N laser reception channels (N is a natural number greater than or equal to 2) are allocated to each of the reception time slots; and
a signal amplification unit configured to sequentially amplify the laser light received by the light receiving unit according to an order of the reception time slots, and having N channels allocated in one-to-one correspondence with the N laser reception channels for each of the reception time slots.

2. The LIDAR device of claim 1, further comprising a transmitting optical system arranged on a transmission path of the laser light transmitted from the light transmitting unit, and configured to form an angle between the laser light and a horizontal axis on the transmission path differently for each of the laser transmission channels.

3. The LIDAR device of claim 2, wherein the transmitting optical system forms an angle between the plurality of laser transmission channels provided in the light transmitting unit and the horizontal axis in a range of −6° to 6°.

4. The LIDAR device of claim 2, further comprising a receiving optical system arranged on a reception path through which the light receiving unit receives the laser light, and configured to form directional angles of the plurality of laser reception channels provided in the light receiving unit differently for each of the laser reception channels.

5. The LIDAR device of claim 1, wherein the transmission time slot and the reception time slot are set to 2 to 3 μs.

6. The LIDAR device of claim 1, wherein the transmission time slot and the reception time slot are allocated so that T time slots (T is a natural number greater than or equal to 2) scan a vertical scan range once,
the light transmitting unit includes T laser transmission channels to which any one of the T transmission time slots is allocated without overlapping, and
the light receiving unit includes T×N laser reception channels, and N laser reception channels may be allocated to each of the reception time slots without overlapping.

7. The LIDAR device of claim 6, wherein T is the same as N.

8. The LIDAR device of claim 6, wherein each of the laser transmission channels includes an edge emitting laser diode.

9. The LIDAR device of claim 1, wherein the transmission time slots and the reception time slots are allocated so that T time slots (T is a natural number greater than or equal to 2) scan a vertical scan range once,
the light transmitting unit includes T×N laser transmission channels, and N laser transmission channels are allocated to each of the transmission time slots without overlapping, and
the light receiving unit includes N laser reception channels, and the N laser reception channels are allocated to each of the reception time slots.

10. The LIDAR device of claim 9, wherein T is the same as N.

11. The LIDAR device of claim 9, wherein each of the laser transmission channels includes a vertical cavity surface emitting laser (VCSEL) diode.

12. The LIDAR device of claim 1, further comprising a signal detection unit configured to detect a signal related to distance calculation from a signal output value of the signal amplification unit.

13. The LIDAR device of claim 12, wherein the signal detection unit detects the signal related to the distance calculation in an analog to digital converter (ADC) method.

14. The LIDAR device of claim 12, wherein the signal detection unit detects the signal related to the distance calculation in a time to digital converter (TDC) method.

15. The LIDAR device of claim 1, further comprising a scanner including a transmission mirror for reflecting the laser light transmitted from the light transmitting unit to the outside, and a reception mirror for reflecting the laser light reflected from the outside to the light receiving unit.

16. The LIDAR device of claim 15, wherein the scanner rotates about a vertical axis.

17. The LIDAR device of claim 16, wherein the transmission mirror forms a horizontal divergence angle of the laser light transmitted from the light transmitting unit to be 0.10° to 0.12°, and the reception mirror forms a horizontal viewing angle of the laser light reflected to the light receiving unit to be 0.11° to 0.13°.
